(19) United States
(12) Patent Application Publication
(10) Pub. No.: US 2016/0011255 A1
(43) Pub. Date: Jan. 14, 2016

(54) SYSTEM AND METHOD TO IDENTIFY AN ELECTRICAL COMPONENT ASSOCIATED WITH A POTENTIAL FAILURE INDICATION FROM A PARTIAL DISCHARGE LISTENING DEVICE

(71) Applicant: General Electric Company, Schenectady, NY (US)

(72) Inventor: Meenanmn Ganesh, Niskayuna, NY (US)

(21) Appl. No.: 14/327,812

(22) Filed: Jul. 10, 2014

(51) Int. Cl. G01R 31/28; G01R 31/02

(52) U.S. Cl. CPC G01R 31/2834; G01R 31/027

(57) ABSTRACT

A monitoring platform may receive a potential failure indication associated with a partial discharge listening device. The potential failure indication may include, for example, information about a distance associated with a potential failure. A database storing information about electrical components associated with the partial discharge listening device may be accessed, the database including information about distances between each electrical component and the partial discharge listening device. The monitoring platform may then automatically identify one of the electrical components as being associated with the potential failure indication based on the information about the received distance and information in the database and generate an alert message indicating the identified electrical component. An overall health score of an electrical substation may be tracked and calculated based on health scores of the individual components at the substation. Moreover, retrofitting an existing substation to incorporate embodiments described herein may be a relatively straightforward task.

### BACKGROUND

Electrical components, such as transformers at an electrical substation, may experience damaging events that can be difficult to detect. As a result of such damage, disruptions to the power grid occur and this can reduce reliability and/or be substantially expensive to correct. For example, the corona effect associated with components in electrical transmission and distribution networks refers to a local electric discharge initiated by gas ionization. This electric discharge may take place under sharply non-uniform electric fields and can be initiated by a relatively small number of electric charges. The origin of such low currents may be, for example, cosmic rays or natural radioactivity. These seeding charges may be accelerated by a radio frequency electric field and subsequent elastic collisions with neutral atoms and ionizations may produce a multiplication of charges. Note that electrical “arcing” may refer to a breakdown of the air when a voltage between two points exceeds the dielectric strength of air. As a result, ionization of the air can occur, and a conductive path may be formed. The arcing and corona discharge can cause serious problems to electrical components and associated cabling. For example, deterioration and an eventual breakdown of a dielectric may cause power outages.

Note that the breakdown voltage may decrease depending on various factors, and the lower breakdown voltage may manifest itself as a “partial discharge” in the voids of a solid insulating material. That is, the deterioration of the insulating material may eventually lead to a complete breakdown of the electrical component. Other environmental factors may also impact the breakdown voltage, such as altitude, pressure, and/or temperature. Moreover, outdoor insulators may face more challenges due to pollution, dust, and/or wetting. These types of deposits may make an insulator non-uniform, and temperature might not be evenly distributed. As a result, local potential gradients may vary on the surface of the insulator causing scintillations or flashovers which can produce radio frequency emissions (e.g., indicating a potential failure in the component). Although radio frequency listening devices may detect these emissions, it may not be known which particular electrical component caused the emission, especially when there are a relatively large number of electrical components near the listening device. As a result, replacing or otherwise fixing the potential problem can be a time consuming and relatively expensive process.

It would therefore be desirable to provide systems and methods to identify electrical components associated with potential failure indications from radio frequency listening devices in an automatic and accurate manner.

### BRIEF DESCRIPTION OF THE DRAWINGS

FIG. 1 is a high-level architecture of a system in accordance with some embodiments.

FIG. 2 illustrates a method that might be performed according to some embodiments.

FIG. 3 illustrates a remote electrical site according to some embodiments.

FIG. 4 is block diagram of a monitoring platform according to some embodiments of the present invention.

FIG. 5 is a tabular portion of a component database according to some embodiments.

FIG. 6 is an example of a display that might be provided in accordance with to some embodiments.

FIG. 7 illustrates a remote electrical site according to some embodiments.

FIG. 8 illustrates a method that might be performed according to some embodiments.

FIG. 9 is a block diagram of an information flow in accordance with some embodiments.

### DETAILED DESCRIPTION

In the following detailed description, numerous specific details are set forth in order to provide a thorough understanding of embodiments. However it will be understood by those of ordinary skill in the art that the embodiments may be practiced without these specific details. In other instances, well-known methods, procedures, components and circuits have not been described in detail so as not to obscure the embodiments.

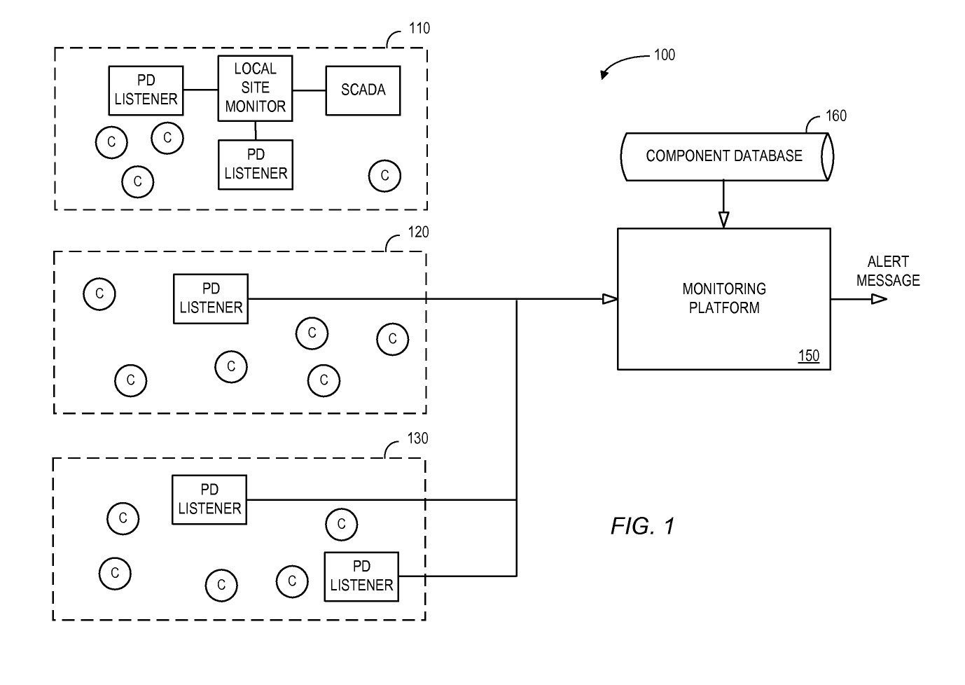

FIG. 1 is a high-level architecture of a system 100 in accordance with some embodiments. The system 100 includes multiple remote electrical sites 110, 120, 130, such as electrical substations, each having a number of electrical components (“C”). Each site may also have one or more Potential Discharge (“PD”) listeners that can transmit potential failure indications to a monitoring platform 150 and/or to a local site monitor. According to some embodiments, a local site monitor may also communication with a Supervisory Control And Data Acquisition (“SCADA”) device. The monitoring platform 150 and/or local site monitor may access information in a component database 160 and automatically generate alert messages as appropriate. As used herein, the term “automatically” may refer to, for example, actions that can be performed with little or no human intervention. Note that alerts from each substation may be conveyed via a network for any given utility company (e.g., in connection with the Industrial Internet). According to some embodiments, a separate local monitoring platform 150 may be provided within each substation 110, 120, 130.

The potential discharge listeners may operate on the principle that when the electric field surrounding a defective energized electrical component (e.g., the bushings on a pole transformer) is disrupted, a characteristic Radio Frequency (“RF”) emission will occur. A data acquisition box may contain antennas and RF receiver circuits that pick up the RF signature emitted by the faulty component. The PD listeners may also have a built in computer that compares the RF signature with known failure signatures. A Global Positioning Satellite (“GPS”) location of the PD listener may be used to generally locate the faulty component. According to some embodiments, the fault data and GPS location data may be transmitted via a cellular network to centralized database server. A web portal may access the database server to produce customer reports. According to some embodiments, a potential failure indicate generated by the PD listener may include information about the distance between the PD listener and the electrical component that has potentially failed.

As used herein, devices, including those associated with the system 100 and any other device described herein, may exchange information via any communication network which may be one or more of a Local Area Network (LAN), a Metropolitan Area Network (MAN), a Wide Area Network (WAN), a proprietary network, a Public Switched Telephone Network (PSTN), a Wireless Application Protocol (WAP) network, a Bluetooth network, a wireless LAN network, and/or an Internet Protocol (IP) network such as the Internet, an intranet, or an extranet. Note that any devices described herein may communicate via one or more such communication networks.

The monitoring platform 150 may store information into and/or retrieve information from the component database 160. The component database 160 may be locally stored or reside remote from the monitoring platform 150. Although a single monitoring platform 150 is shown in FIG. 1, any number of such devices may be included. Moreover, various devices described herein might be combined according to embodiments of the present invention. For example, in some embodiments, the monitoring platform 150 and component database 160 might comprise a single apparatus.

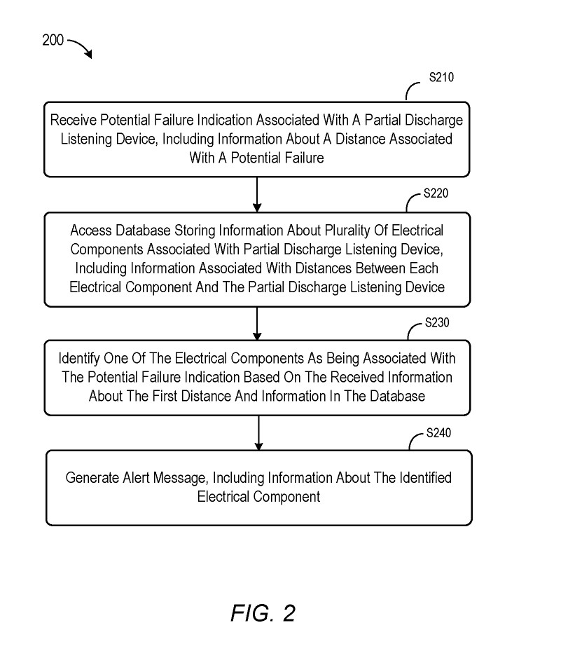

The system 100 may identify electrical components associated with potential failure indications from radio frequency listening devices in an automatic and accurate manner in accordance with any of the embodiments described herein. For example, FIG. 2 illustrates a method 200 that might be performed by some or all of the elements of the system 100 described with respect to FIG. 1. The flow charts described herein do not imply a fixed order to the steps, and embodiments of the present invention may be practiced in any order that is practicable. Note that any of the methods described herein may be performed by hardware, software, or any combination of these approaches. For example, a computer-readable storage medium may store thereon instructions that when executed by a machine result in performance according to any of the embodiments described herein.

At S210, a monitoring platform may receive a potential failure indication associated with a partial discharge listening device (e.g., a radio frequency failure signature detector). Moreover, the first potential failure indication may include information about a distance associated with a potential failure.

At S220, a database storing information about a plurality of electrical components associated with the partial discharge listening device may be accessed. The database may include, for example, information associated with distances between each electrical component and the first partial discharge listening device. Note that the database might be a database that is locally stored at each substation or may instead be stored remotely. For example, a utility might store databases for multiple substations within a cloud computing environment. As used herein, the term “electrical component” may refer to, for example, a device associated an electrical substation, a transformer, an arrester, and/or an insulator. The information associated with distances between each electrical component and the partial discharge listening device stored in the database might be associated with, for example, pixels, coordinates, latitudes and longitudes, and/or GPS information. According to some embodiments, the database simply stores the actual distance between the components and the PD listener (e.g., component X is 45 meters away from this particular PD listener).

At S230, the monitoring platform may automatically identify one of the electrical components as being associated with the potential failure indication based on the information about the first distance and information in the database. For example, the electrical component having a distance from the PD listener that most closely matches the one distance associated with the potential failure may be identified.

At S240, the monitoring platform may generate an alert message, including information about the identified electrical component. The information about the identified electrical component in the alert message might include, for example, a component identifier, a component type, a remote electrical site identifier, a failure type, a time and date, and/or information about other potential failures associated with the identified electrical component. According to some embodiments, the monitoring platform may track potential failure indications for the electrical components over a period of time. Moreover, the monitoring platform may be associated with an electrical substation and may further calculate a health score of the electrical substation based on the potential failure indications that were tracked over the period of time. That is, an overall health score of an electrical substation may be tracked and calculated based on health scores of the individual components at the substation. Note that retrofitting an existing substation to incorporate any of the embodiments described herein, including the tracking of an overall health score, may be a relatively straightforward task.

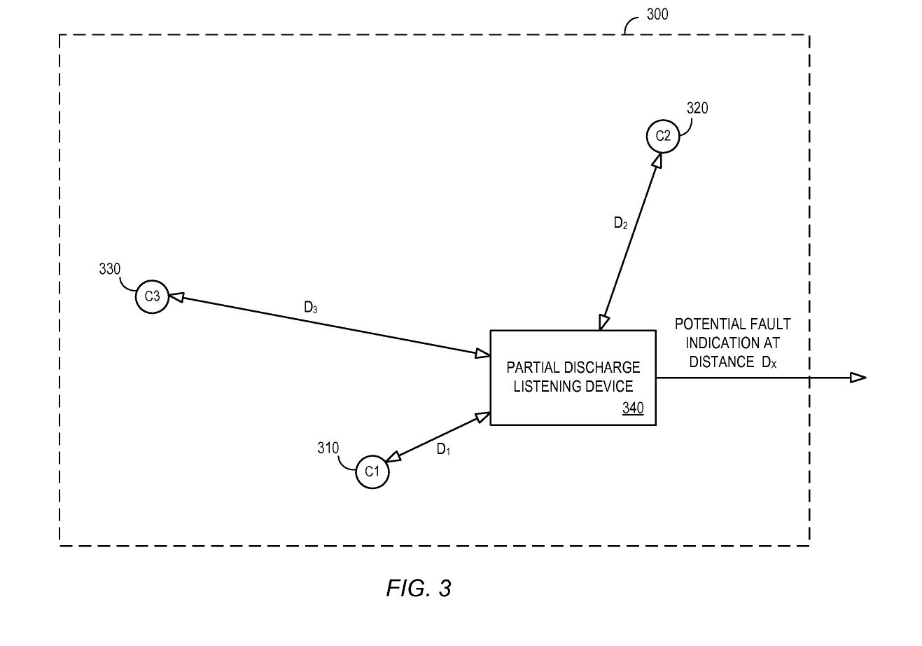

Consider, for example, FIG. 3, which illustrates a remote electrical site 300 according to some embodiments. The electrical site 300 may include any number of electrical components 310, 320, 330 (labeled C1 through C3 in FIG. 3). The remote electrical site 300 also includes a partial discharge listening device 340. Each electrical component 310, 320, 330 is located a distance D from the partial discharge listening device 340 (C1 is D₁ away from the partial listening device 340, etc.). When the partial discharge listening device 340 detects an RF failure signature, it may transmit a potential fault indication including an approximate distance associated with the failure (e.g., based on the strength of the RF failure signature). The potential fault indication may be transmitted, for example, to a remote monitoring platform.

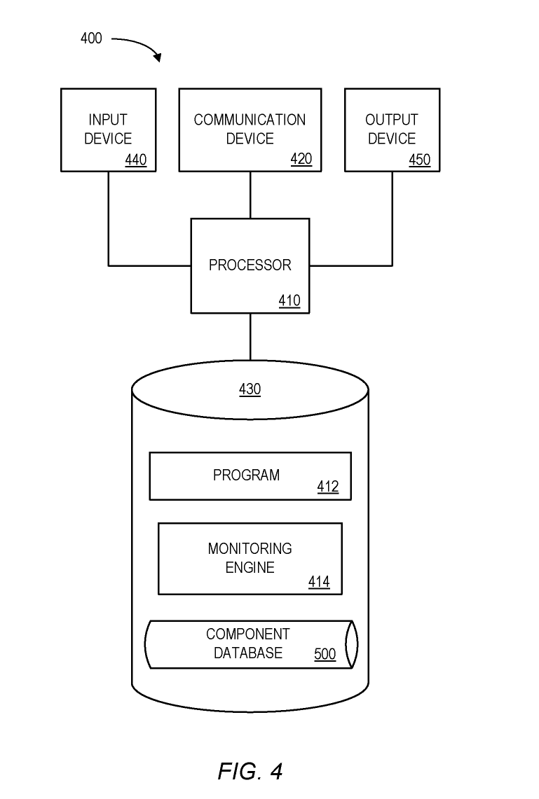

The embodiments described herein may be implemented using any number of different hardware configurations. For example, FIG. 4 is block diagram of a monitoring platform 400 that may be, for example, associated with the system 100 of FIG. 1. The monitoring platform 400 comprises a processor 410, such as one or more commercially available Central Processing Units (CPUs) in the form of one-chip microprocessors, coupled to a communication device 420 configured to communicate via a communication network (not shown in FIG. 4). The communication device 420 may be used to communicate, for example, with one or more remote devices (e.g., to communicate with remote PD listeners). The monitoring platform 400 further includes an input device 440 (e.g., a computer mouse and/or keyboard to input distance and/or mapping information) and an output device 450 (e.g., a computer monitor to display alerts and/or reports). According to some embodiments, a mobile device and/or voice activated messages may be used to exchange information with the monitoring platform 400.

The processor 410 also communicates with a storage device 430. The storage device 430 may comprise any appropriate information storage device, including combinations of magnetic storage devices (e.g., a hard disk drive), optical storage devices, mobile telephones, and/or semiconductor memory devices. The storage device 430 stores a program 412 and/or a monitoring engine 414 for controlling the processor 410. The processor 410 performs instructions of the programs 412, 414, and thereby operates in accordance with any of the embodiments described herein. For example, the processor 410 may receive a potential failure indication associated with a partial discharge listening device. The potential failure indication may include, for example, information about a distance associated with a potential failure. A component database 500 storing information about electrical components associated with the partial discharge listening device may be accessed by the processor 410, the database including information associated with distances between each electrical component and the partial discharge listening device. The processor 410 may then automatically identify one of the electrical components as being associated with the potential failure indication based on the information about the received distance and information in the component database 500 and generate an alert message, including information about the identified electrical component.

The programs 412, 414 may be stored in a compressed, uncompiled and/or encrypted format. The programs 412, 414 may furthermore include other program elements, such as an operating system, clipboard application a database management system, and/or device drivers used by the processor 410 to interface with peripheral devices.

As used herein, information may be “received” by or “transmitted” to, for example: (i) the monitoring platform 400 from another device; or (ii) a software application or module within the monitoring platform 400 from another software application, module, or any other source.

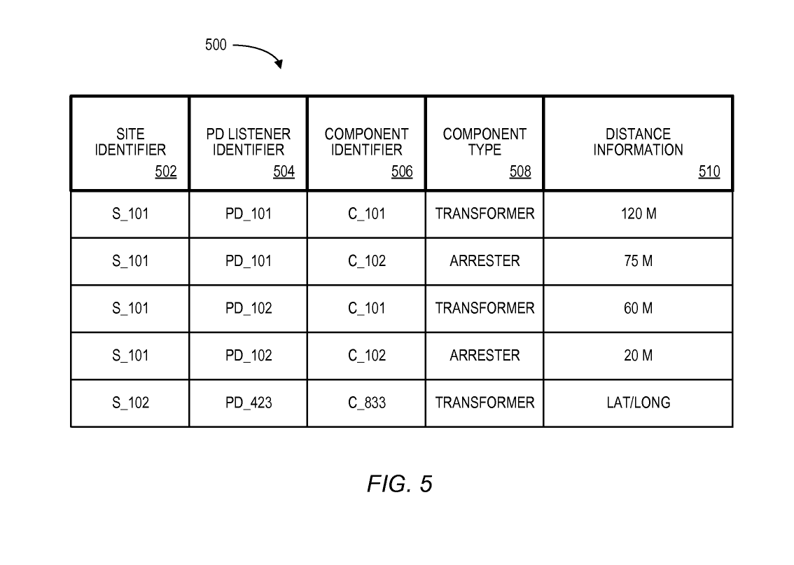

In some embodiments (such as shown in FIG. 4), the storage device 430 stores the component database 500. An example of a database that may be used in connection with the monitoring platform 400 will now be described in detail with respect to FIG. 5. Note that the database described herein is only one example, and additional and/or different information may be stored therein. Moreover, various databases might be split or combined in accordance with any of the embodiments described herein.

Referring to FIG. 5, a table is shown that represents the component database 500 that may be stored at the monitoring platform 400 according to some embodiments. The table may include, for example, entries identifying electrical components associated with a power grid. The table may also define fields 502, 504, 506, 508, 510 for each of the entries. The fields 502, 504, 506, 508, 510 may, according to some embodiments, specify: a site identifier 502, a PD listener identifier 504, a component identifier 506, a component type 508, and distance information 510. The component database 500 may be created and updated, for example, when a monitoring platform is created and/or as component are added to or removed from a substation, moved in location, etc.

The site identifier 502 may be, for example, a unique alphanumeric code identifying an electrical substation. The PD listener identifier 504 may identify an RF failure signature detector at that site, and the component identifier 506 may be associated with a particular electronic device at the site. For example, substation “S_101” may have two PD listeners (“PD_101” and “PD_102”) and two electrical components (“C_101” and “C_102”) as illustrated in FIG. 5. The component type 508 may describe the electrical component (e.g., as being a “transformer” or “arrester”), and the distance information 510 might identify how far the component is located from a particular PD listener. Thus, if a potential failure indication was received from “PD_101” indicated that the failure as approximately 110 meters away, a monitoring platform might identifier “C_101” as the likely source of the failure (because the distance information 510 for “C_101” more closely matches as compared to “C_102”).

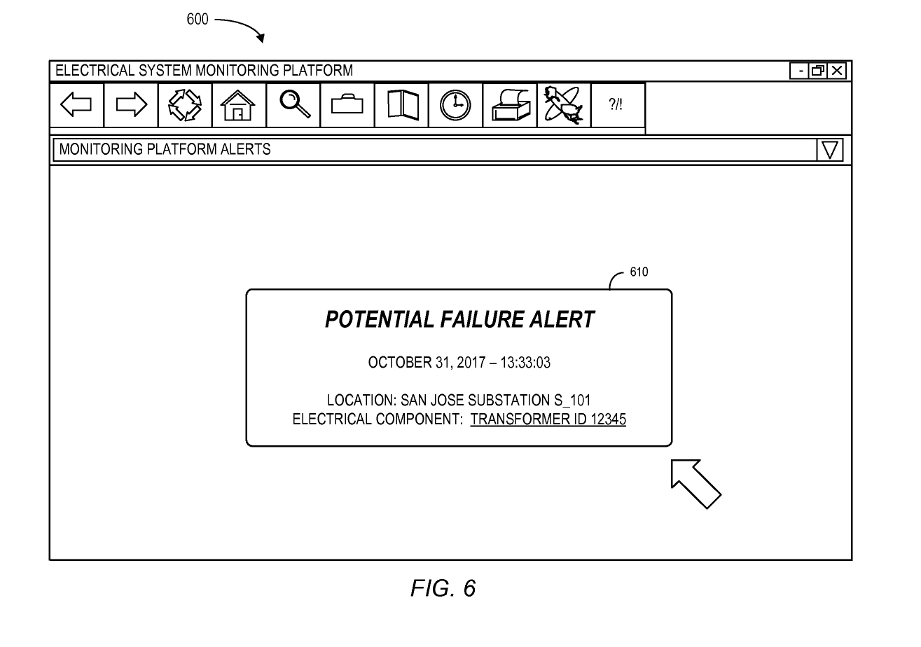

FIG. 6 is an example of a display 600 that might be provided when a potential fault is detected in accordance with to some embodiments. In particular, the display 600 includes a potential failure alert 610 indicating the date and time of the potential failure. The alter 610 also include site location information and identifies that particular component that most likely triggered the alert (e.g., transformer ID 12345). This information may then be used, for example, to repair or replace the component to help avoid future problems, such as power outages, etc.

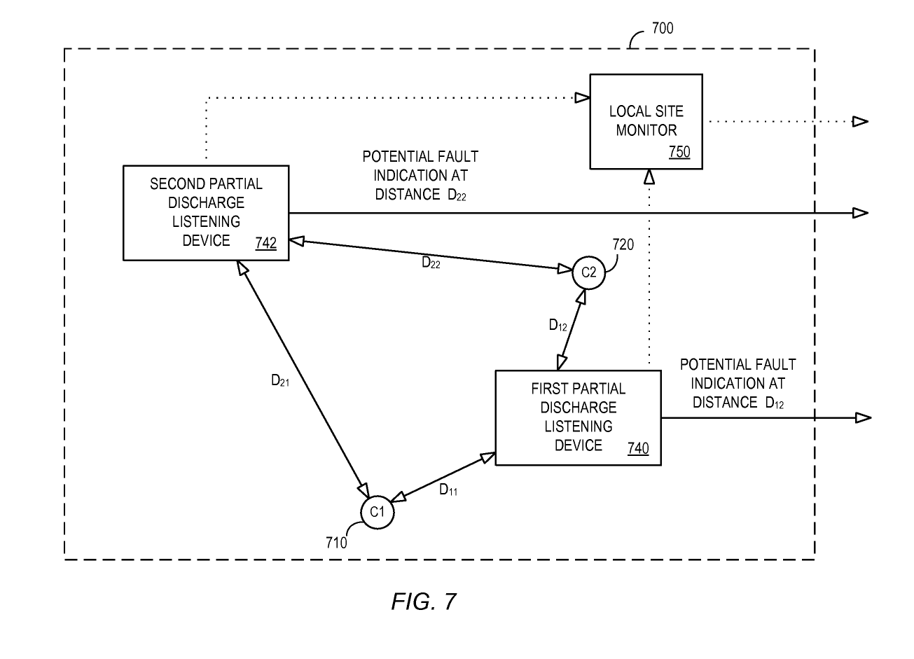

In some of the examples described herein, a single PD listener may be provided at an electrical site. Note, however, that multiple PD listeners at a single site may be used to improve the accuracy of the system. Consider, for example, FIG. 7, which illustrates a remote electrical site 700 according to some embodiments. The electrical site 700 includes two electrical components 710, 720 (labeled C1 and C2 in FIG. 7). The remote electrical site 700 also includes a first partial discharge listening device 740 and a second partial discharge listening device 742. Each electrical component 710, 720 is located a distance D from the partial discharge listening devices 740, 742 (C1 is D₁₁ away from the first partial listening device 740 and D₂₁ away from the second partial listening device 740, etc.). When the first partial discharge listening device 740 detects an RF failure signature from component C2, it may transmit a potential fault indication including an approximate distance associated with the failure (e.g., based on the strength of the RF failure signature). The potential fault indication may be transmitted, for example, to a remote monitoring platform. Note, however, that both C1 and C2 are approximately the same distance from the first partial discharge listening device 740, and, as a result, the system may be unable to determine which component triggered the potential fault indication. According to this embodiment, information from the second partial discharge listing device 742 (triggered by the same potential failure) may be used to resolve the issue. According to some embodiments, the partial discharge listening devices 740, 742 may communicate directly with a remote monitoring platform. According to other embodiments, the partial discharge listening devices 740, 742 instead communicate through a locate site monitor 750 (which might locally identify the component or simply relay the distance information to a remote monitoring platform).

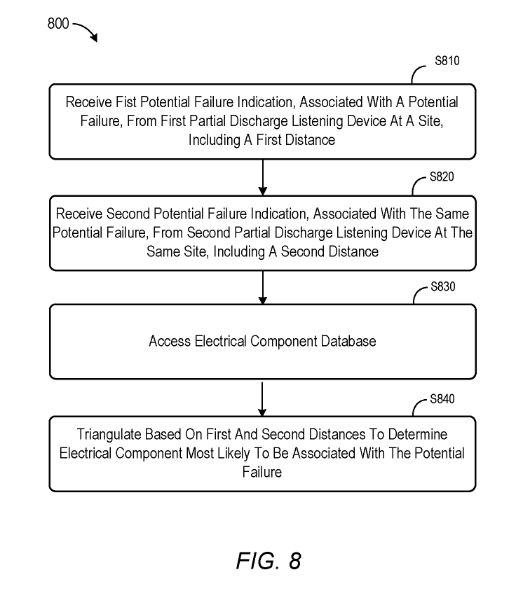

FIG. 8 illustrates a method 800 that might be performed according to some embodiments. At S810, a first potential failure indication may be received from a first partial discharge listening device at an electrical site. The first potential failure indication may be associated with a potential failure that occurred at a first distance. At S820, a second potential failure indication may be received from a second partial discharge listening device at that electrical site. The second potential failure indication may be associated with a potential failure that occurred at second distance. An electrical component database may be accessed at S830, and the system may triangulate at S840 based on the first and second distances to determine an electrical component most likely to be associated with the potential failure.

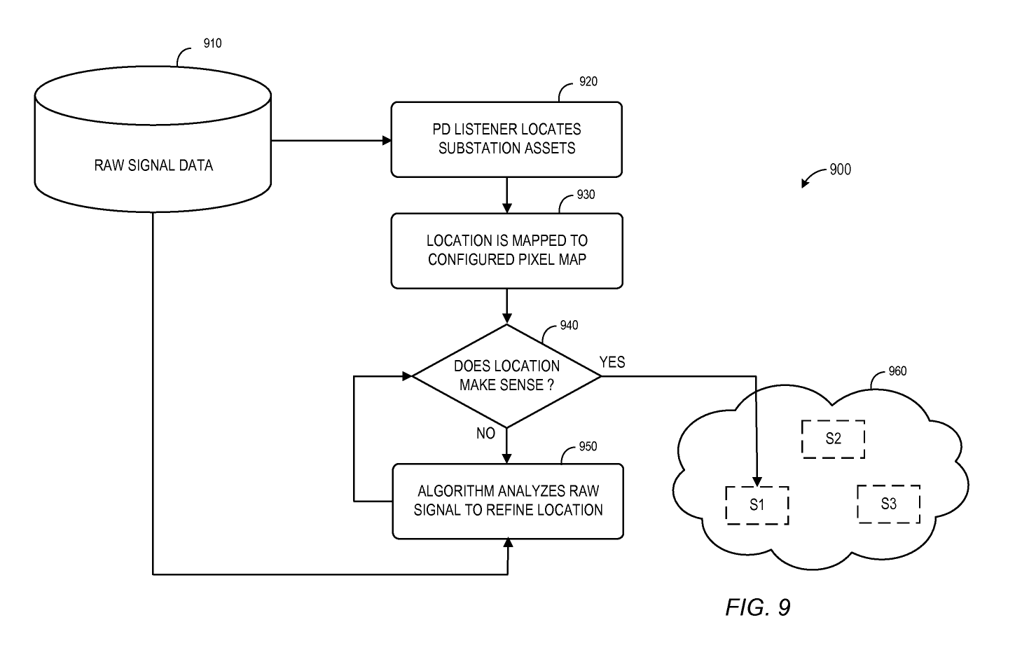

FIG. 9 is a block diagram of an information flow 900 in accordance with some embodiments. In particular, raw signal data 910 may be provided so that a PD listener can locate substation assets 920. The location may be mapped to a configure pixel map 930, and, if the location does not make sense at 940, an algorithm may analyze the raw signal data 910 to refine the location at 950. When the location makes sense at 940, it may be mapped to a particular substation (e.g., S1) in an industrial internet and/or smart grid in a computational cloud 960. Note that the cloud 960 may receive asset alerts from multiple substations, and a utility might receive a combined dashboard of asset alerts. For example, asset alerts might be used to derive a “health index” for one or more assets.

Thus, some embodiments described here may use PD listeners to locate the exact location of an asset within the substation. In response to an alert, a utility might validate the faulty component in the substation and/or derive a useful life of the asset by trending a number of faults seen by the same asset. Moreover, one or two PD listeners in a substation may provide fault data for several assets. According to some embodiments, PD listeners may be used along with a configured spatial map of an electrical substation, and algorithms may refine asset locations. Moreover, in some embodiments, the devices may be connected to the industrial cloud, and a utility company may determine an overall picture of all of the assets in their control.

The configuration of an asset map at a substation might be a onetime effort (until a new asset is added to the substation or an asset is moved). The configuration could, for example, give a pixel-based or other coordinate location of each asset with respect to an origin. That may provide an inexpensive way of monitoring several assets in a substation to determine the health of the assets. According to some embodiments, an overall health of a substation may be monitored instead (e.g., even if the health of each asset within the substation is not tracked). Note that when the health of an asset is computed, a utility may be able to plan for the purchase and deployment of new assets.

The following illustrates various additional embodiments of the invention. These do not constitute a definition of all possible embodiments, and those skilled in the art will understand that the present invention is applicable to many other embodiments. Further, although the following embodiments are briefly described for clarity, those skilled in the art will understand how to make any changes, if necessary, to the above-described apparatus and methods to accommodate these and other embodiments and applications.

Although specific hardware and data configurations have been described herein, note that any number of other configurations may be provided in accordance with embodiments of the present invention (e.g., some of the information associated with the databases described herein may be combined or stored in external systems).

The present invention has been described in terms of several embodiments solely for the purpose of illustration. Persons skilled in the art will recognize from this description that the invention is not limited to the embodiments described, but may be practiced with modifications and alterations limited only by the spirit and scope of the appended claims.

1. A method, comprising:
receiving, at a monitoring platform, a first potential failure indication associated with a first partial discharge listening device, the first potential failure indication including information about a first distance associated with a potential failure;
accessing a database storing information about a plurality of electrical components associated with the first partial discharge listening device, including information associated with distances between each electrical component and the first partial discharge listening device;
automatically identifying, by the monitoring platform, one of the electrical components as being associated with the first potential failure indication based on the information about the first distance and information in the database; and
generating an alert message, including information about the identified electrical component.

2. The method of claim 1, wherein the first partial discharge listening device comprises a radio frequency failure signature detector.

3. The method of claim 1, wherein at least one of the electrical components is associated with at least one of: (i) an electrical substation, (ii) a transformer, (iii) an arrester, and (iv) an insulator.

4. The method of claim 1, further comprising:
tracking potential failure indications for the electrical components over a period of time.

5. The method of claim 1, wherein the monitoring platform is associated with an electrical substation, and calculating a health score of the electrical substation based on the potential failure indications tracked over the period of time.

6. The method of claim 1, wherein the monitoring platform is associated with a plurality of partial discharge listening devices.

7. The method of claim 8, wherein the plurality of partial discharge listening devices are associated with a plurality of remote electrical substations operated by a utility.

8. The method of claim 7, wherein at least one of the remote electrical substations is associated with more than one partial discharge listening device.

9. The method of claim 8, further comprising:
receiving, at the monitoring platform, a second potential failure indication associated with a second partial discharge listening device of the plurality of partial discharge listening devices, the second potential failure indication including information about a second distance associated with the potential failure,
wherein said automatic identification of the electrical components is further based on the information about the second distance.

10. The method of claim 1, wherein the information about the identified electrical component in the alert message includes at least one of: (i) a component identifier, (ii) a component type, (iii) a remote electrical site identifier, (iv) a failure type, (v) a time and date, and (vi) information about other potential failures associated with the identified electrical component.

11. The method of claim 1, wherein the information associated with distances between each electrical component and the first partial discharge listening device stored in the database is associated with at least one of: (i) pixels, (ii) coordinates, (iii) latitudes and longitudes, (iv) global positioning system information, and (v) distances.

12. A non-transitory, computer-readable medium storing instructions that, when executed by a computer processor, cause the computer processor to perform a method associated with a plurality of partial discharge listening devices, the method comprising:
receiving, at a monitoring platform, a first potential failure indication associated with a first partial discharge listening device of the plurality of partial discharge listening devices, the first potential failure indication including information about a first distance associated with a potential failure;
accessing a database storing information about a plurality of electrical components associated with the first partial discharge listening device, including information associated with distances between each electrical component and the first partial discharge listening device;
automatically identifying, by the monitoring platform, one of the electrical components as being associated with the first potential failure indication based on the information about the first distance and information in the database; and
generating an alert message, including information about the identified electrical component.

13. The medium of claim 12, wherein the partial discharge listening devices comprise radio frequency failure signature detectors.

14. The medium of claim 12, wherein at least one of the electrical components is associated with at least one of: (i) an electrical substation, (ii) a transformer, (iii) an arrester, and (iv) an insulator.

15. The medium of claim 12, wherein the plurality of partial discharge listening devices are associated with a plurality of remote electrical sites.

16. The medium of claim 12, wherein at least one of the remote electrical sites is associated with more than one partial discharge listening device.

17. The medium of claim 16, wherein the method further comprises:
receiving, at the monitoring platform, a second potential failure indication associated with a second partial discharge listening device of the plurality of partial discharge listening devices, the second potential failure indication including information about a second distance associated with the potential failure,
wherein said automatic identification of the electrical components is further based on the information about the second distance.

18. The medium of claim 12, wherein the information about the identified electrical component in the alert message includes at least one of: (i) a component identifier, (ii) a component type, (iii) a remote electrical site identifier, (iv) a failure type, (v) a time and date, and (vi) information about other potential failures associated with the identified electrical component.

19. The method of claim 12, wherein the information associated with distances between each electrical component and the first partial discharge listening device stored in the database is associated with at least one of: (i) pixels, (ii) coordinates, (iii) latitudes and longitudes, (iv) global positioning system information, and (v) distances.

20. A monitoring platform associated with a plurality of partial discharge listening devices, comprising:
a database storing information about a plurality of electrical components associated with a first partial discharge listening device, including information associated with distances between each electrical component and the first partial discharge listening device;
a communication port to receive a first potential failure indication associated with a first partial discharge listening device of the plurality of partial discharge listening devices, the first potential failure indication including information about a first distance associated with a potential failure; and
a monitoring engine to: (i) automatically identify one of the electrical components as being associated with the first potential failure indication based on the information about the first distance and information in the database, and (ii) generate an alert message, including information about the identified electrical component.

21. The monitoring platform of claim 20, wherein the partial discharge listening devices comprise radio frequency failure signature detectors and at least one of the electrical components is associated with at least one of: (i) an electrical substation, (ii) a transformer, (iii) an arrester, and (iv) an insulator.

22. The monitoring platform of claim 20, wherein the plurality of partial discharge listening devices are associated with a plurality of remote electrical sites and at least one of the remote electrical sites is associated with more than one partial discharge listening device, wherein the monitoring engine is further to receive a second potential failure indication associated with a second partial discharge listening device of the plurality of partial discharge listening devices, the second potential failure indication including information about a second distance associated with the potential failure,
wherein said automatic identification of the electrical components is further based on the information about the second distance.

23. The monitoring platform of claim 20, wherein the information about the identified electrical component in the alert message includes at least one of: (i) a component identifier, (ii) a component type, (iii) a remote electrical site identifier, (iv) a failure type, (v) a time and date, and (vi) information about other potential failures associated with the identified electrical component.

24. The monitoring platform of claim 20, wherein the information associated with distances between each electrical component and the first partial discharge listening device stored in the database is associated with at least one of: (i) pixels, (ii) coordinates, (iii) latitudes and longitudes, (iv) global positioning system information, and (v) distances.
